(19) United States
(12) Patent Application Publication
(10) Pub. No.: US 2022/0392874 A1
(43) Pub. Date: Dec. 8, 2022

(54) RED LED CHIP COMPONENT, RED LED CHIP, DISPLAY PANEL AND MANUFACTURING METHOD

(71) Applicant: CHONGQING KONKA PHOTOELECTRIC TECHNOLOGY REASEARCH INSTITUTE CP., LTD., Chongqing (CN)

(72) Inventors: Feng ZHAI, Chongqing (CN); Chun-lung HSIAO, Chongqing (CN)

(21) Appl. No.: 17/770,117

(22) PCT Filed: Mar. 22, 2021
(86) PCT No.: PCT/CN2021/082077

§ 371 Date: Apr. 19, 2022

(30) Foreign Application Priority Data
Sep. 24, 2020 (CN) 202011013915.8

(51) Int. Cl. H01L 25/075; H01L 33/14; H01L 33/38; H01L 33/00; H01L 33/62

(52) U.S. Cl. CPC H01L 25/0753; H01L 33/14; H01L 33/382; H01L 33/0093; H01L 33/62; H01L 2933/0016

(57) ABSTRACT

The present disclosure relates to a red LED chip component, a red LED chip, a display panel and a manufacturing method. The red LED chip component includes an insulating substrate and a plurality of red LED chips arranged on the insulating substrate. The red LED chip and the insulating substrate are bonded by a thermal release adhesive layer.

### CROSS REFERENCE TO RELATED APPLICATION

The present application claims priority to Chinese Patent Application No. 202011013915.8, entitled “Red LED Chip Component, Red LED Chip, Display Panel and Manufacturing Method”, filed on Sep. 24, 2020, the content of which is expressly incorporated herein by reference in its entirety.

### TECHNICAL FIELD

The present disclosure relates to the field of the Light Emitting Diode (LED) technology, and particularly to a red LED chip component, a red LED chip, a display panel and a manufacturing method.

### BACKGROUND

At present, the LED high-definition display solutions are inseparable from red, green, and blue LED chips. The final manufacturing process of the LED chips of the three colors is carried out on a sapphire substrate. After the manufacturing is completed, a laser is required to separate the LED chips from the sapphire substrate. Such technological process is mature and simple for the blue or green LED chips. But for the red LED chip, because the red epitaxial layer and the Indium Tin Oxide (ITO) layer are formed on the growth substrate during the manufacturing process, the red LED chip is actually is transferred to the sapphire substrate through the Benzocyclobutene (BCB) adhesive, accordingly the lift off of the sapphire substrate is actually the decomposition of the BCB adhesive layer. However, the BCB adhesive has dissatisfied absorption of the laser, thus such process often requires a higher laser energy; but the laser energy may damage the ITO layer. In order to prevent the red LED chip from being damaged, it is necessary to increase the thickness of the ITO layer, and the increase in the thickness of the ITO layer may also lead to an increase in its internal stress, which in turn makes the electrodes arranged on the ITO layer fall off easily, thereby affecting the reliability of the red LED chip and reducing the quality of the red LED chip.

Therefore, how to improve the quality of red LED chip is an urgent problem to be solved.

### SUMMARY

In view of the above-mentioned deficiencies of the related technology, the purpose of the present disclosure is to provide a red LED chip component, a red LED chip, a display panel and a manufacturing method thereof, and is intended to solve the problem of low reliability of the red LED chip in the related technology.

The present discloses provides a red LED chip component, including:

an insulating substrate;

a plurality of red LED chips arranged on the insulating substrate; and

a thermal release adhesive layer configured to bond the insulating substrate and the red LED chip;

the red LED chip includes a current spreading layer in contact with the thermal release adhesive layer, a red light epitaxial layer on the current spreading layer, and electrodes respectively electrically connected to two semiconductor layers in the red light epitaxial layer; and the thermal release adhesive layer is configured to bond the current spreading layer and the insulating substrate in a process of transferring the red light epitaxial layer from a growth substrate to the insulating substrate.

The above-mentioned red LED chip component includes the insulating substrate and a plurality of red LED chips provided on the insulating substrate. During the manufacturing process of the red LED chips, the red light epitaxial layer and the current spreading layer are transferred to the insulating substrate through the bonding of the current spreading layer and the thermal release adhesive layer. Accordingly, the thermal release adhesive layer absorbs the heat to fail when the insulating substrate is peeled off, and there is no need to use the laser lift off, and the current spreading layer is naturally not damaged by the laser energy. On this basis, there is no need to increase the thickness of the current spreading layer, which is beneficial to ensure the reliability of the connection between the electrodes and the current spreading layer, and improve the quality of the red LED chip. Moreover, the present disclosure achieves the purpose of peeling off the insulating substrate by making the thermal release adhesive layer fail, thereby avoiding the problem of residual adhesive on the red LED chip caused by incomplete decomposition of the BCB adhesive layer with the laser, and improving the display effect of the red LED chip, and further enhancing the quality of the red LED chip.

Based on the same inventive concept, the present disclosure further provides a method for manufacturing a red LED chip component, including:

providing a growth substrate and a red light epitaxial layer formed on a surface of the growth substrate;

providing a current spreading layer on the red light epitaxial layer;

bonding the current spreading layer and an insulating substrate through a thermal release adhesive layer;

removing the growth substrate to transfer the red light epitaxial layer from the growth substrate to the insulating substrate; and

providing electrodes on the red light epitaxial layer to form the red LED chip component including a red LED chip.

In the above-mentioned method for manufacturing the red LED chip component, a current spreading layer is provided on the red light epitaxial layer located on the surface of the growth substrate, a thermal release adhesive layer is utilized to bond the current spreading layer and the insulating substrate, and the growth substrate is removed to transfer the red light epitaxial layer from the growth substrate to the insulating substrate, and electrodes are provided on the red light epitaxial layer on the insulating substrate. During the process for manufacturing the red LED chip, the current spreading layer is bonded and transferred to the insulating substrate through the thermal release adhesive layer, accordingly, the red LED chip and the insulating substrate are bonded through the thermal release adhesive layer. When the insulating substrate is peeled off, as long as the thermal release adhesive layer absorbs the heat and fails, no laser lift off is required, and the current spreading layer is naturally not damaged by the laser energy. On this basis, there is no need to increase the thickness of the current spreading layer, which is beneficial to ensure the reliability of the connection between the electrodes and the current spreading layer, thereby improving the quality of the red LED chip. Moreover, the present disclosure achieves the purpose of peeling off the insulating substrate by making the thermal release adhesive layer fail, thereby avoiding the problem of leaving residual adhesive on the red LED chip caused by incomplete decomposition of the BCB adhesive layer with the laser, and improving the display effect of the red LED chip, and further enhancing the quality of the red LED chip.

Based on the same inventive concept, the present disclosure further provides a method for manufacturing a red LED chip, including:

manufacturing a red LED chip component according to the method for manufacturing the red LED chip component of any one of the above embodiments; and

heating up to make the thermal release adhesive layer fail and separate the insulating substrate from the red LED chip.

In the above-mentioned method for manufacturing the red LED chip, because the red light epitaxial layer of the red LED chip is bonded and transferred to the insulating substrate through the bonding of the current spreading layer and the thermal release adhesive layer, so that the red LED chip and the insulating substrate are bonded through the thermal release adhesive. After the manufacturing of the red LED chip component is completed, when the insulating substrate is peeled off, as long as the thermal release adhesive layer absorbs the heat and fails, there is no need to use the laser to decompose the BCB adhesive layer, and the current expansion layer is naturally not damaged by the laser energy. On this basis, there is no need to increase the thickness of the current spreading layer, which is beneficial to ensure the reliability of the connection between the electrodes and the current spreading layer, thereby improving the quality of the red LED chip. Moreover, the present disclosure achieves the purpose of peeling off the insulating substrate by making the thermal release adhesive layer fail, thereby avoiding the problem of leaving residual adhesive on the red LED chip caused by incomplete decomposition of the BCB adhesive layer with the laser, and improving the display effect of the red LED chip, and further enhancing the quality of the red LED chip.

Based on the same inventive concept, the present disclosure further provides a method for manufacturing a display panel, including:

manufacturing a red LED chip component according to the method for manufacturing the red LED chip component of any one of the above embodiments; an arrangement of each red LED chip in the red LED chip component satisfies a deployment requirement of the red LED chip on a driver backplane;

soldering an electrode of each red LED chip in the real LED chip component to a solder joint on the driver backplane;

after the thermal release adhesive layer fails due to heating, removing the insulating substrate and the failed thermal release adhesive layer.

In the above-mentioned method for manufacturing the display panel, a red LED chip component is first manufactured by the aforementioned method for manufacturing the red LED chip component, and the arrangement of the red LED chips on the red LED chip component satisfies the deployment requirement of the red LED chips on the driver backplane. Therefore, when the display panel is manufactured, the red LED chip component can be directly bound to the driver backplane as a whole, and then the insulating substrate can be removed after the thermal release adhesive layer fails. In the method for manufacturing the display panel, the red LED chip and the insulating substrate are bonded by the thermal release adhesive layer. Accordingly, when the insulating substrate is peeled off, as long as the thermal release adhesive layer absorbs the heat and fails, there is no need to use the laser to decompose the BCB adhesive layer, and the current spreading layer is naturally not damaged by the laser energy. On this basis, there is no need to increase the thickness of the current spreading layer, which is beneficial to ensure the reliability of the connection between the electrodes and the current spreading layer, thereby improving the quality of the red LED chip. Moreover, the present disclosure achieves the purpose of peeling off the insulating substrate by making the thermal release adhesive layer fail, thereby avoiding the problem of leaving residual adhesive on the red LED chip caused by incomplete decomposition of the BCB adhesive layer with the laser, and improving the display effect of the red LED chip, and further enhancing the quality of the red LED chip. On the other hand, in the process of manufacturing the display panel, the plurality of red LED chips on the insulating substrate can be directly transferred to the driver backplane, and there is no need to use a temporary substrate for transfer, which simplifies the transfer procedure of the red LED chips, improves the manufacturing efficiency of the display panel and is conducive to saving cost.

Based on the same inventive concept, the present disclosure further provides a display panel, which is manufacture by the method for manufacturing the display panel in any one of the above embodiments.

As for the above-mentioned display panel, in the manufacturing process, the red LED chip component is first manufactured by the aforementioned method for manufacturing the red LED chip, and the arrangement of the red LED chips on the red LED chip component satisfies the deployment requirement of the red LED chips on the driver backplane. Accordingly, when the display panel is manufactured, the red LED chip component can be directly bound to the driver backplane as a whole, and then the insulating substrate can be removed after the thermal release adhesive layer fails. In the method for manufacturing the display panel, the red LED chip and the insulating substrate are bonded by the thermal release adhesive layer, so that when the insulating substrate is peeled off, as long as the thermal release adhesive layer absorbs the heat and fails, there is no need to use the laser to decompose the BCB adhesive layer, and the current spreading layer is naturally not damaged by the laser energy. On this basis, there is no need to increase the thickness of the current spreading layer, which is beneficial to ensure the reliability of the connection between the electrodes and the current spreading layer, thereby improving the quality of the red LED chip. Moreover, the present disclosure achieves the purpose of peeling off the insulating substrate by making the thermal release adhesive layer fail, thereby avoiding the problem of leaving residual adhesive on the red LED chip caused by incomplete decomposition of the BCB adhesive layer with the laser, and improving the display effect of the red LED chip, and further enhancing the quality of the red LED chip. On the other hand, during the process of manufacturing the display panel, the plurality of red LED chips on the insulating substrate can be directly transferred to the driver backplane, and there is no need to use a temporary substrate for the transfer, which simplifies the transfer procedure of the red LED chips, improves the manufacturing efficiency of the display panel and is conducive to saving cost.

### BRIEF DESCRIPTION OF THE DRAWINGS

FIG. 1 is a schematic diagram of a state change in a process of manufacturing a red LED in the related art shown in the present disclosure.

FIG. 2 is a flow chart showing a method for manufacturing a red LED chip component according to an optional embodiment of the present disclosure.

FIG. 3 is a schematic diagram of a state change in each manufacture procedure of a process of manufacturing a red LED chip component according to an optional embodiment of the present disclosure.

FIG. 4 is a flow chart of transferring a red light epitaxial layer and a current spreading layer to an insulating substrate according to an optional embodiment of the present disclosure.

FIG. 5 is another flow chart of transferring a red light epitaxial layer and a current spreading layer to an insulating substrate according to an optional embodiment of the present disclosure.

FIG. 6 is a schematic diagram of a state change in a process of transferring the red light epitaxial layer and the current spreading layer to the insulating substrate in FIG. 5.

FIG. 7 is a schematic structure diagram of a red LED chip on an insulating substrate according to an optional embodiment of the present disclosure.

FIG. 8 is another schematic structure diagram of a red LED chip on an insulating substrate according to an optional embodiment of the present disclosure.

FIG. 9 is a flow chart showing a method for manufacturing a red LED chip according to another optional embodiment of the present disclosure.

FIG. 10 is a flow chart showing a method for manufacturing a display panel according to another optional embodiment of the present disclosure.

FIG. 11 is a schematic diagram of a principle of lift off an insulating substrate according to another optional embodiment of the present disclosure.

FIG. 12 is a flow chart showing a method for manufacturing a red LED chip component according to another optional embodiment of the present disclosure.

FIG. 13 is a schematic diagram of a state change in each manufacture procedure of a process of manufacturing a red LED chip component according to another optional embodiment of the present disclosure.

### DESCRIPTION OF REFERENCE SIGNS

110, GaAs substrate; 111, N-type semiconductor layer; 112, active layer; 113, P-type semiconductor layer; 114, ITO layer; 115, BCB adhesive layer; 120, sapphire substrate; 30, red LED chip component; 300, red LED chip; 301, growth substrate; 302, insulating substrate; 31, red light epitaxial layer; 32, current spreading layer; 33, thermal release adhesive layer; 34, insulating protection layer; 113, failed thermal release adhesive layer; 1141, insulating protection layer on a side portion of thermal release adhesive layer; 1142, insulating protection layer on an upper portion of thermal release adhesive layer; 131, GaAs substrate; 132, red light epitaxial layer; 133, ITO layer; 134, thermal release adhesive layer; 135, sapphire substrate; 136, silicon oxide layer; 137, driver backplane.

### DETAILED DESCRIPTION

In order to facilitate understanding of the present disclosure, the present disclosure will be described more comprehensively below with reference to the related accompanying drawings. Preferred embodiments of the present disclosure are shown in the accompanying drawings. However, the present disclosure can be implemented in many different forms and is not limited to the embodiments described herein. Rather, these embodiments are provided to make the understanding of the content of the present disclosure more thorough and comprehensive.

Unless otherwise defined, all technical and scientific terms used herein have the same meaning as commonly understood by one of ordinary skill in the technical field to which the present disclosure relates. The terms used herein in the specification of the present disclosure are merely for the purpose of describing specific embodiments, and are not intended to limit the present disclosure.

At present, in the manufacturing scheme of the LED high-definition display screen, the red, green and blue LED chips are soldered to the drive substrate. Each pixel point consists of red, green and blue LED chips; and the pixel points are arranged in a lattice structure. The LED chips in each pixel point can be driven independently and can support the brightness adjustment of the red, green and blue LED chips respectively.

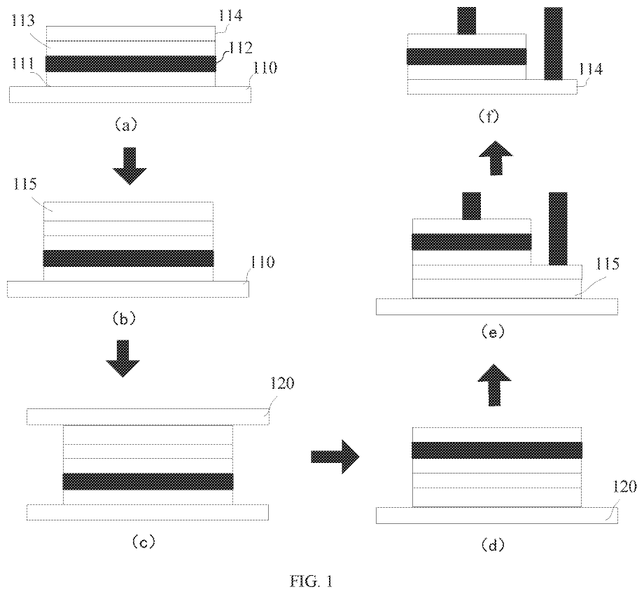

When the red, green and blue LED chips are manufactured, for the blue and green LED chips, a gallium nitride (GaN)-based structure can grow directly on the sapphire substrate. Since the sapphire substrate material is non-conductive, the blue or green LED chip can be directly manufactured on the sapphire substrate after the GaN-based structure grows. However, for the red LED chip, an aluminum gallium indium phosphorous (AlGaInP)-based structure generally grows on a gallium arsenide (GaAs) substrate. Referring to (a) in FIG. 1, because an energy gap of the GaAs substrate 110 is smaller than an energy gap of the red light epitaxial layer growing on the GaAs substrate, the light emitted by the active layer is easily absorbed, which further reduces the luminous brightness of the red LED chip. After the N-type semiconductor layer 111, the active layer 112 and the P-type semiconductor layer 113 grow, and the ITO layer 114 is deposited, the red light epitaxial layer needs to be transferred to the sapphire substrate 120 to continue to complete the manufacturing of the red LED chip. In the related technologies, the BCB adhesive is usually spin-coated on the ITO layer 114 to form the BCB adhesive layer 115, referring to (b) in FIG. 1, and then the red light epitaxial layer is transferred to the sapphire substrate 120 by using the adhesion of the BCB adhesive layer 115, as shown in (c) and (d) in FIG. 1.

After the red light epitaxial layer is transferred to the sapphire substrate 120, electrodes respectively connected to two semiconductor layers are provided, in which one electrode is directly provided on a first semiconductor layer, and the other electrode is provided on the ITO layer to electrically connect to a second semiconductor layer through the ITO layer, as shown in (e) of FIG. 1. After the LED chip is manufactured, the LED chip needs to be peeled off from the sapphire substrate. The most common lift off method at present is Laser Lift Off (LLO). The essence of the LLO is because of the absorption of a particular band of laser light by a material, specifically, the material absorbs the photon energy, so that the electrons transition to an excited state, and the sapphire substrate is separated from the LED chip by using the principle of GaN→Ga+N2. GaN material has a high absorption rate for the laser light, so that the blue and green LED chips can be more completely separated from the sapphire substrate. But in the red LED chip, the essence of the lift off of the sapphire substrate from the red LED chip is decomposition of the BCB adhesive layer, as shown in (f) in FIG. 1. However, there are at least the following two problems in the decomposition of the BCB adhesive layer by the laser light.

First, the laser light may damage the ITO layer. In order to prevent the damage of the ITO layer from affecting the electrical properties of the red LED chip, the thickness of the ITO layer needs to be increased. However, the increase in the thickness of the ITO layer may inevitably lead to an increase in the internal stress thereof, and the increase in the internal stress may cause the electrodes provided on the ITO layer to fall off easily, thereby affecting the reliability of the red LED chip.

Second, the BCB has dissatisfied absorption of the laser light. Such process is purely based on a physical impact to carbonize and decompose the BCB adhesive. In this case, the problem of residual adhesive or incomplete removing of the adhesive is prone to occur, which results in residual adhesive left on the red LED chip, thereby affecting the display effect of the red LED chip.

Based on this, the present disclosure intends to provide a solution that can solve the above technical problems, and the details of which will be described in the subsequent embodiments.

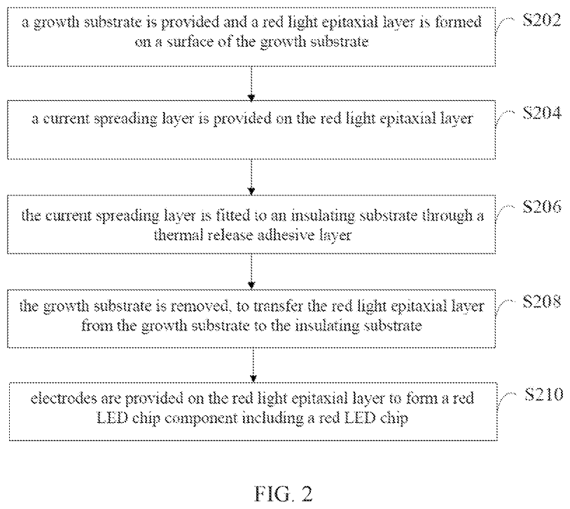

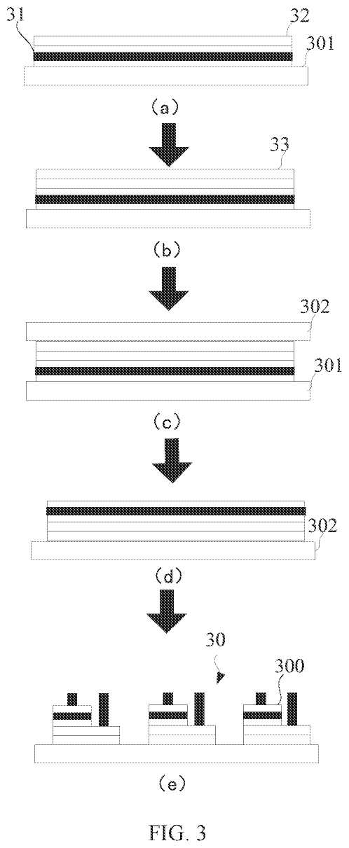

In the embodiment, a method for manufacturing a red LED chip component and a red LED chip component manufactured based on the method are firstly provided. Referring to the flow chart of the method for manufacturing the red LED chip component shown in FIG. 2, and the schematic diagram of the state change in each manufacture procedure of the process of manufacturing the red LED chip component shown in FIG. 3:

S202: a growth substrate is provided and a red light epitaxial layer is formed on a surface of the growth substrate.

In the embodiment, the red light epitaxial layer of the red LED chip includes a first semiconductor layer, a second semiconductor layer, and an active layer provided between the first semiconductor layer and the second semiconductor layer. It can be appreciated that, one of the first semiconductor layer and the second semiconductor layer is an N-type semiconductor layer, and the other is a P-type semiconductor layer.

It can be appreciated that, when the growth substrate and the red light epitaxial layer formed on the surface of the growth substrate are provided, the red light epitaxial layer that has grown on the growth substrate in advance can be used, without dedicatedly growing and forming a red light epitaxial layer. Alternatively, a growth substrate can be temporarily provided in the process of manufacturing the red LED chip component, and the red light epitaxial layer can grow on the growth substrate.

S204: a current spreading layer is provided on the red light epitaxial layer.

In consideration of the dissatisfied dispersion capability of a semiconductor layer in the red LED chip to a hole, which is easy to cause electrons to directly pass through the active layer from one electrode to the other electrode on another semiconductor layer with the shortest path, thereby causing nonuniform light output of the red LED chip. Therefore, in some examples of the embodiment, the red light epitaxial layer 31 is also provided with a current spreading layer 32 which is configured to uniformly disperse the holes on the entire surface of the semiconductor layer, thereby improving the uniformity of the light output of the red LED chip. In the embodiment, when the red light epitaxial layer 31 is located on the growth substrate 301, the first semiconductor layer is located under the second semiconductor layer, as shown in FIG. 3(a). Therefore, the current spreading layer 32 is provided on the red light epitaxial layer 31, that is actually the current spreading layer 32 is provided on the second semiconductor layer of the red light epitaxial layer 31, and the current spreading layer 32 can be fitted to the second semiconductor layer.

In some examples of the embodiment, the current spreading layer 32 can be an ITO layer. Of course, those skilled in the art can understand that the ITO layer is not the only feasible current spreading layer 32. For example, in some other examples of the embodiment, the current spreading layer 32 can be an acrylic resin layer dispersed with silver nanowires, as long as the current spreading layer 32 has good electrical conductivity and can implement a hole transport function.

S206: the current spreading layer is fitted to an insulating substrate through a thermal release adhesive layer.

The red light epitaxial layer usually grows on a growth substrate made of the gallium arsenide material. Since the growth substrate 301 made of the gallium arsenide material is inadaptable for the subsequent procedure of manufacturing the red LED chip, so that in the embodiment, after the red light epitaxial layer 31 grows, the red light epitaxial layer 31 is transferred to the insulating substrate. In order to implement the transfer of the red light epitaxial layer 31, in the related technologies, a BCB adhesive layer is provided on the red light epitaxial layer 31, and the adhesiveness of the BCB adhesive layer is utilized to complete the combination of the red light epitaxial layer 31 and the insulating substrate. In the embodiment, in order to avoid the problem of incomplete removing of the BCB adhesive layer during the process of the laser lift off, and to avoid the problem of damaging the current spreading layer 32 by the laser light when the BCB adhesive layer is peeled off, the BCB adhesive layer is no longer provided, but the thermal release adhesive layer 33 is adopted to combine the red light epitaxial layer 31 and the insulating substrate.

S208: the growth substrate is removed, to transfer the red light epitaxial layer from the growth substrate to the insulating substrate.

In order to transfer the red light epitaxial layer 31 from the growth substrate 302 to the insulating substrate, in addition to forming the bond of the red light epitaxial layer 31 and the insulating substrate 302, the growth substrate 301 needs to be removed.

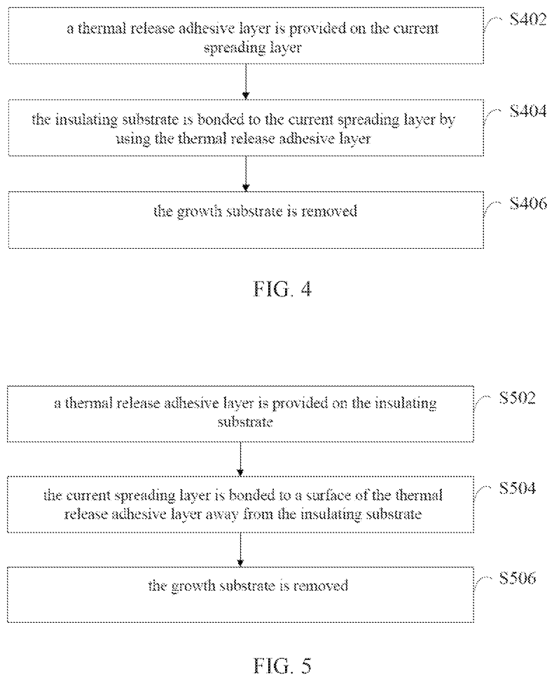

In some examples of this embodiment, the procedure shown in FIG. 4 can be utilized to provide the thermal release adhesive layer 33 and implement the transfer of the red light epitaxial layer 31 and the current spreading layer 32.

S402: a thermal release adhesive layer is provided on the current spreading layer.

As shown in FIG. 3(b), a thermal release adhesive layer 33 is provided on the current spreading layer 32. The thermal release adhesive is usually an adhesive material of acrylic system. As the name suggests, the thermal release adhesive may debond when heated; and the higher the temperature, the less sticky the material. It should be understood that the thermal release adhesive layer 32 should have adhesiveness during the manufacturing process of the red LED chip component, so that a failure temperature of the thermal release adhesive layer 32 should be higher than a temperature of an environment in which the red LED chip component is manufactured.

S404: the insulating substrate is bonded onto the current spreading layer by using the thermal release adhesive layer.

The thermal release adhesive layer 33 has adhesiveness, and one surface thereof adheres onto the current spreading layer 21; the other surface thereof can be configured to adhere to the insulating substrate 302, as shown in FIG. 3(c). In the embodiment, the insulating substrate 302 can include, but is not limited to, a sapphire substrate.

S406: the growth substrate is removed.

In the red LED chip, the current spreading layer 32 can be combined with the insulating substrate 302 through the thermal release adhesive layer 33. On the other hand, it is also necessary to separate the red light epitaxial layer 31 from the growth substrate 301 thereof, as shown in FIG. 3(d). According to the foregoing description, the growth substrate of the red LED chip is made of gallium arsenide. Therefore, in some examples of the embodiment, the growth substrate 301 can be removed by wet etching or the like.

In other examples of the embodiment, the thermal release adhesive layer 33 can be provided and the transfer of the red light epitaxial layer 31 and the current spreading layer 32 may be implement with reference to the procedure shown in FIG. 5.

S502: a thermal release adhesive layer is provided on the insulating substrate.

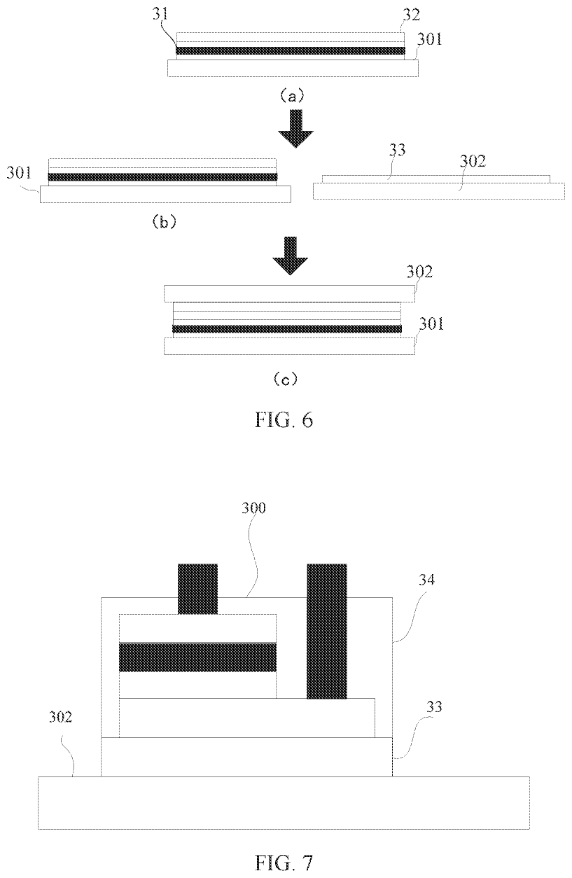

The main difference between the procedures in FIG. 5 and FIG. 4 lies in different process of providing the thermal release adhesive layer 33. In the example of FIG. 5, the thermal release adhesive layer 33 is first provided on the insulating substrate 302, referring to the schematic diagrams of state changes in processes shown in FIGS. 6(a) and 6(b).

S504: the current spreading layer is bonded to a surface of the thermal release adhesive layer away from the insulating substrate.

After the thermal release adhesive layer 33 is provided on the insulating substrate 302, the thermal release adhesive layer 33 together with the insulating substrate 302 can be transferred to the current spreading layer 32; a surface of the insulating substrate 302 provided with the thermal release adhesive layer 33 is arranged to approximate to the current spreading layer 32 until the thermal release adhesive layer 33 is bonded to the current spreading layer 32, as shown in FIG. 6(c).

S506: the growth substrate is removed.

When the growth substrate 301 is removed, the wet etching and other modes can also be used, which will not be repeated here.

In some examples of the embodiment, thermal release adhesive layers can also be simultaneously provided on the insulating substrate and the current spreading layer, and then the two thermal release adhesive layers are bonded, for example, a first thermal release adhesive is provided on the current spreading layer, and a second thermal release adhesive layer is provided on the insulating substrate, then the first thermal release adhesive layer is bonded to the second thermal release adhesive layer, and then the growth substrate is removed.

S210: electrodes are provided on the red light epitaxial layer to form a red LED chip component including a red LED chip.

After the current spreading layer 32 and the red light epitaxial layer 31 are transferred to the insulating substrate 302, electrodes respectively electrically connected to the first semiconductor layer and the second semiconductor layer in the red light epitaxial layer 31 can be provided. Compared to a front-mounted and vertical structure chip, electrodes of a flip-chip LED chip do not need to be wired, which can effectively reduce the packaging area, reduce the chip size, and increase the display pixels, which is conducive to the manufacturing of the high-definition display screen. Therefore, the red LED chip in the embodiment can be a flip-chip LED chip. It can be understood that, in the red LED chip with the flip-chip structure, the two electrodes are located on a surface at the same side of the red light epitaxial layer, that is, an electrode deployment surface of the red light epitaxial layer 31. For the red LED chip with the flip-chip structure, the electrode deployment surface is a surface of the red light epitaxial layer 31 away from the insulating substrate 302. Apparently, those skilled in the art can understand that, in some other examples of the embodiment, the red LED chip can also be a chip with a front-mounted structure.

For the two electrodes of the red LED chip, the first electrode should be electrically connected to the first semiconductor layer, and the second electrode should be electrically connected to the second semiconductor layer. In consideration of directly providing the second electrode on the second semiconductor layer, the electrons may directly pass through the active layer and the first semiconductor layer from the electrode arrangement region to the first electrode in the shortest path, and do not laterally diffuse on the second semiconductor layer, which leads to the problem of nonuniform light output of the red LED chip. Therefore, in the embodiment, the second electrode is provided on the current spreading layer 32, that is, the electrode arrangement region of the second electrode is located on the current spreading layer 32, and the second electrode is electrically connected to the second semiconductor layer through the current spreading layer 32. However, after the red light epitaxial layer 31 is transferred onto the insulating substrate 302. the current spreading layer 32 is covered and obscured by the red light epitaxial layer 31. Therefore, in order to provide the electrodes, the red light epitaxial layer 31 needs to be patterned to expose the electrode arrangement region of the second electrode.

After the electrode arrangement regions of the two electrodes are exposed, the electrodes can be provided. In some examples of the embodiment, an electrode metal layer can be formed on the electrode arrangement region by using a technology such as evaporation or Physical Vapour Deposition (PVD), and then the electrode metal layer is patterned to form the first electrode and the second electrode. FIG. 3(e) is a schematic diagram of providing the second electrode on the current spreading layer 32.

After the electrodes are provided, the red LED chip component 30 is substantially manufactured. It can be appreciated that the red light epitaxial layer which grows on the growth substrate 301 can usually be configured to form a plurality of red LED chips. Accordingly, after the electrodes are provided, there may be a plurality of red LED chips 300 on the insulating substrate 302. Therefore, in the embodiment, the red LED chip component 30 includes the insulating substrate 302,thea thermal release adhesive layer 33, and a plurality of red LED chips 300 bonded to the insulating substrate 302 through the thermal release adhesive layer 33.

In some examples of the embodiment, referring to FIG. 7 and FIG. 8, the red LED chip 300 further includes an insulating protection layer 34; and the insulating protection layer 34 can cover the red light epitaxial layer 31. In some examples of the embodiment, the insulating protection layer 34 and the thermal release adhesive layer 33 together wrap the red LED chip, and only a partial electrode region of the red LED chip 300 is exposed, in order to electrically connect to an external electrical structure. It can be appreciated that, after the insulating protection layer 34 and the thermal release adhesive layer 33 wrap the red LED chip 300, only the partial electrode region of the red LED chip 300 can be exposed; or, in some other examples of the embodiment, in addition to the electrodes, the red LED chip 300 may also have other exposed regions. Undoubtedly, the insulating protection layer 34 is made of an insulating material, which can insulate the red light epitaxial layer 31 and the current spreading layer 32 from the electrical influence of the external electrical structure. Of course, the insulating protection layer 34 can also form a physical protection for the red LED chip 300, which covers the red light epitaxial layer 31 and the current spreading layer 32 inside, thereby reducing the possibility of external impact damage to the red LED chip. In some examples of the embodiment, in order to prevent the insulating protection layer 34 from affecting the light output of the red LED chip 300, so that in the embodiment, the insulating protection layer 34 may also be made of a transparent material. In some examples, the material of the insulating protection layer 34 includes, but is not limited to, silicon oxide (SiO₂).

In some examples of the embodiment, the insulating protection layer 34 only wraps the red LED chip 300, and without wrapping the thermal release adhesive layer 33, that is, the insulating protection layer 34 is only located on one side of the thermal release adhesive layer 33, as shown in FIG. 7. However, in the actual production process, the insulating protection layer 34 can also wrap a side surface of the thermal release adhesive layer 33 and is in contact with the insulating substrate 302, as shown in FIG. 8. It can be understood that even if the insulating protection layer 34 wrap the side surface of the thermal release adhesive layer 33, in actual production, the insulating protection layer 34 wrapping the thermal release adhesive layer 33 is not too thick, that is, the insulating protection layer 34 wrapping the side surface of the thermal release adhesive layer 33 is not too thick. Therefore, due to the occupation of the thermal release adhesive layer 33, the insulating protection layer 34 does not form a solid layer structure on a plane where the thermal release adhesive layer 33 is located, but can only form a “weakened structure” on the side surface of the thermal release adhesive layer 33. When the thermal release adhesive layer 33 fails, by applying a pressure to the insulating substrate 302 toward the red LED chip 300 side, the insulating protection layer 34 on the side surface of the thermal release adhesive layer 33 is separated from the insulating protection layer 34 on the thermal release adhesive layer 33, so that the insulating substrate 302 is detached from the red LED chip 300.

In some examples of the embodiment, any two points on a surface of the insulating protection layer 34 away from the insulating substrate 302 are on the same horizontal plane, that is, the surface of the insulating protection layer 34 away from the insulating substrate 302 is flat. Therefore, the insulating protection layer 34 is actually a flat layer of the red LED chip 300, which can make the surface of the red LED chip more regular.

Optionally, the insulating protection layer 34 can be provided before the electrodes are provided. For example, after the red light epitaxial layer 31 is transferred from the growth substrate 301 to the insulating substrate 302, a plurality of red light epitaxial layers are simultaneously arranged on the insulating substrate 302, these red light epitaxial layers can be configured to form a plurality of red LED chips. In the example, before electrodes are provided on each of the red light epitaxial layers 31 on a surface of each insulating substrate, insulating protection layers 34 can be provided on the plurality of red light epitaxial layers 31 respectively; the insulating protection layer 34 and the thermal release adhesive layer 33 can together wrap the red light epitaxial layer 31 and the current spreading layer 32. In some examples of the embodiment, the insulating protection layer 34 and the thermal release adhesive layer 33 can completely wrap the red light epitaxial layer 31 and the current spreading layer 32. In the process of providing the electrodes, the insulating protection layer 34 can patterned to expose the electrode arrangement, thereby implementing the electrode arrangement. In some other examples of the embodiment, the insulating protection layer 34 and the thermal release adhesive layer 33 can also incompletely wrap the red light epitaxial layer 31 and the current spreading layer 32. For example, at least one of the red light epitaxial layer 31 and the current spreading layer 32 can have a partial region exposed. Optionally, in some examples of the embodiment, when the insulating protection layer 34 is formed, the insulating protection layer 34 is ensured not to cover the electrode arrangement region. In such a manner, in the subsequent procedure of arranging the electrodes, an etching process for the insulating protection layer 34 can also be avoided.

It can be understood that when a red light epitaxial layer grows on the growth substrate 301, a larger-area red light epitaxial layer can grow, and then a plurality of independent red light epitaxial layers can be obtained by processing such as cutting and etching the larger-area red light epitaxial layer. Undoubtedly, the process of dividing the large-area red epitaxial layer into a plurality of independent red epitaxial layers can be accomplished on the growth substrate 301, or can be accomplished after transferred to the insulating substrate 302.

In other examples of the embodiment, the insulating protection layer 34 can be provided after the electrodes are provided, in order to ensure that a partial electrode region of the red LED chip is exposed to the insulating protection layer 34, without specially etching the insulating protection layer 34.

In the red LED chip component provided in the embodiment, the red light epitaxial layer and the current spreading layer are transferred by using the thermal release adhesive layer instead of the BCB adhesive layer. Therefore, in the subsequent process of lifting off the insulating substrate, no laser is required, which avoids the damage to the current spreading layer by the laser, and accordingly there is no need to increase the thickness of the current spreading layer, which is beneficial to ensure the reliability of the electrodes arranged on the current spreading layer and improve the quality of the red LED chip. Further, as long as the temperature reaches the failure temperature of the thermal release adhesive layer, the thermal release adhesive layer can lose the adhesiveness thereof, and no adhesive residue is bonded to the red LED chip, which ensures the display effect of the red LED chip and enhances the quality of red LED chip.

Another optional embodiment:

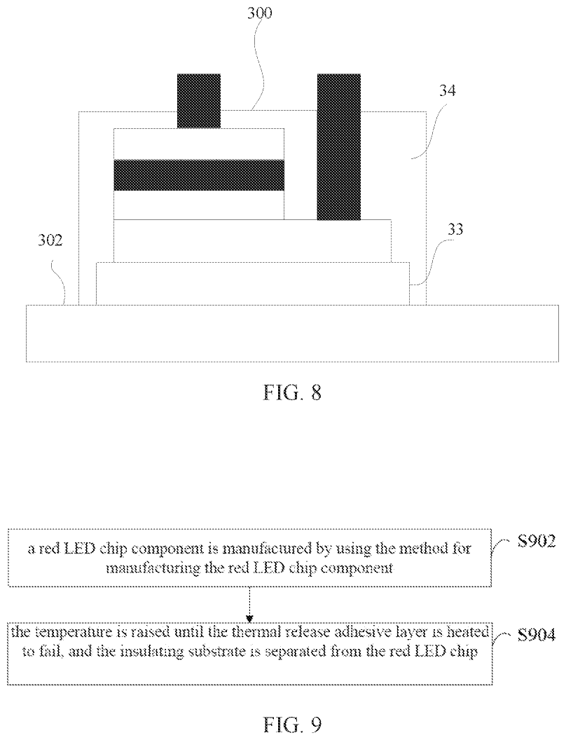

Based on the foregoing method for manufacturing the red LED chip component, in this embodiment a method for manufacturing a red LED chip is provided, referring to a flow chart showing a method for manufacturing a red LED chip shown in FIG. 9.

S902: a red LED chip component is manufactured by using the method for manufacturing the red LED chip component.

For the method for manufacturing the red LED chip component, please refer to the description of the foregoing embodiment, which will not be repeated here.

S904: the temperature is raised until the thermal release adhesive layer is heated to fail, and the insulating substrate is separated from the red LED chip.

After the red LED chip component is manufactured, the thermal release adhesive layer can be made fail by heating up, thereby unbinding the insulating substrate from the red LED chip, in order to achieve the purpose of separating the insulating substrate from the red LED chip.

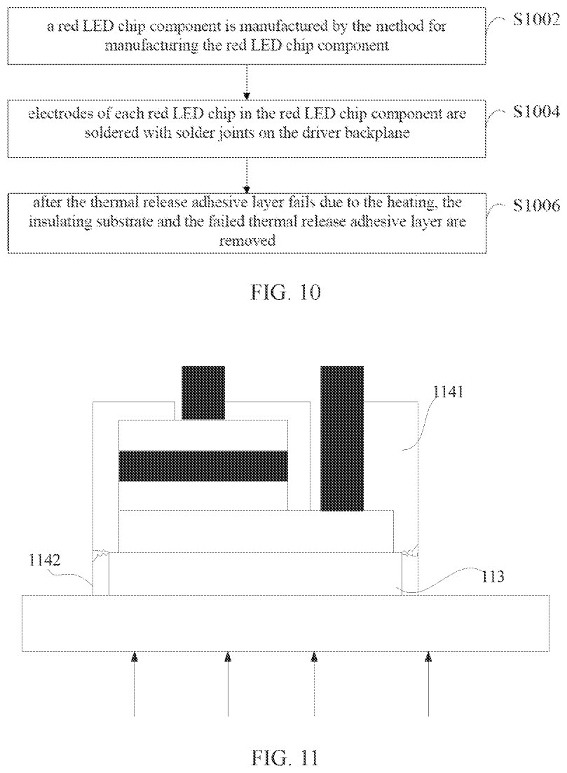

In the embodiment, a method for manufacturing a display panel is further provided, referring to the flow chart shown in FIG. 10.

S1002: a red LED chip component is manufactured by the method for manufacturing the red LED chip component.

For the method for manufacturing the red LED chip component, please refer to the description of the foregoing embodiment, which will not be repeated here.

It should be noted that, in the embodiment, the arrangement of the red LED chips in the red LED chip component satisfies the deployment requirements of the red LED chips on the driver backplane. Therefore, in the process of manufacturing the red LED chip component, the number and spacing of the red light epitaxial layers need to be specially designed according to the deployment requirements of the red LED chips on the driver backplane. For example, on the driver backplane, a distance between an arrangement region of a red LED chip “a” and tan arrangement region of a red LED chip “c” is D, then a distance between the red LED chip “a” and the red LED chip “c” in the red LED chip component is also D.

S1004: electrodes of each red LED chip in the red LED chip component are soldered with solder joints on the driver backplane.

After the red LED chip component is manufactured, the red LED chips in the red LED chip component can be uniformly transferred to the driver backplane through the insulating substrate, and meanwhile the electrodes of each red LED chip are electrically connected to the driver backplane. That is, the electrodes of each red LED chip are soldered to the corresponding solder joints on the driver backplane.

S1006: after the thermal release adhesive layer fails due to the heating, the insulating substrate and the failed thermal release adhesive layer are removed.

After the red LED chips in the red LED chip component are soldered to the driver backplane, the insulating substrate can be removed. Since the red LED chip and the insulating substrate are bonded by the thermal release adhesive layer, the thermal release adhesive layer can fail by heating up, thereby lifting off the insulating substrate.

In some examples of the embodiment, heat is transferred to the thermal release adhesive layer through the insulating substrate by heating a side of the insulating substrate away from the red LED chip. However, in consideration of a higher temperature and more heat that are generated during the process of soldering the electrodes of the red LED chip, so that in some examples of the embodiment, the high temperature generated during the soldering process can be directly utilized to make the thermal release adhesive layer fail. In some examples of the embodiment, it can be ensured that the soldering temperature is higher than the failure temperature of the thermal release adhesive layer, so that the thermal release adhesive layer can fail during the soldering process. For example, the solder can be indium or bismuth metal. When the metal indium is used as the solder, the soldering temperature is about 158° C.; when the metal bismuth is used as the solder, the soldering temperature is about 98° C.

In some other examples, the red LED chip further includes an insulating protection layer; and the insulating protection layer also wraps the side surface of the thermal release adhesive layer and is in contact with the insulating substrate. It can be understood that the contact between the insulating protection layer and the insulating substrate actually also forms the bonding of the insulating substrate and the insulating protection layer. Therefore, only the failure of the thermal release adhesive layer does not make the insulating substrate separate from the red LED chip. Therefore, in some examples, after the thermal release adhesive layer fails, the bonding between the insulating substrate and the insulating protection layer needs to be further destroyed.

Referring to FIG. 11, since the failed thermal release adhesive layer 113 has a certain elasticity, the insulating substrate has a certain deformation space in a region where the thermal release adhesive layer is located. At the same time, since the insulating protection layer wrapping the side surface of the thermal release adhesive layer is not thick, accordingly, compared to the insulating protection layer on the upper portion of the thermal release adhesive layer, the insulating protection layer on the side portion of the thermal release adhesive layer is not a solid and reliable layer structure, but a “weakened structure”. Therefore, by applying a pressure to the insulating substrate toward the red LED chip side, the insulating protection layer 1141 wrapping the side surface of the thermal release adhesive layer can be broken and separated from the insulating protection layer 1142 wrapping the upper portion of the thermal releasing adhesive layer.

In the embodiment, a display panel is further provided, which is manufactured by using the aforementioned method for manufacturing the display panel. The display panel includes a driver backplane and a plurality of red LED chips electrically connected to the driver backplane. it should be understood that, in addition to the red LED chips, the display panel may also include blue LED chips and green LED chips.

In the display panel and the manufacturing method thereof provided in the embodiment, the red LED chip component is first manufactured, in which the arrangement of the red LED chips of the red LED chip component satisfies the deployment requirements of the red LED chips on the driver backplane, and then the red LED chip component can be directly bound to the driver backplane as a whole, and the insulating substrate is removed after the thermal release adhesive layer fails, thereby avoiding the use of a temporary substrate for transfer, simplifying the transfer procedure of red LED chips, improving the manufacturing efficiency of the display panel, which is conducive to saving cost.

At the same time, the thermal release adhesive layer determines that the current spreading layer is not damaged by the laser in the process of lifting off the insulating substrate. Therefore, the process of manufacturing the red LED chip does not need to increase the thickness of the current spreading layer, which is beneficial to ensure the reliability of the connection between the electrodes and the current spreading layer, thereby improving the quality of the red LED chip. Moreover, in the process of lifting off the insulating substrate, no adhesive residue is left on the red LED chip, which improves the light output effect of the red LED chip, and is beneficial to enhance the display quality of the display panel.

Another optional embodiment:

In order to make the advantages and details of the foregoing red LED chip component, display panel and manufacturing method thereof clearer to those skilled in the art, the above-mentioned solution will continue to be described in the embodiment in combination with examples.

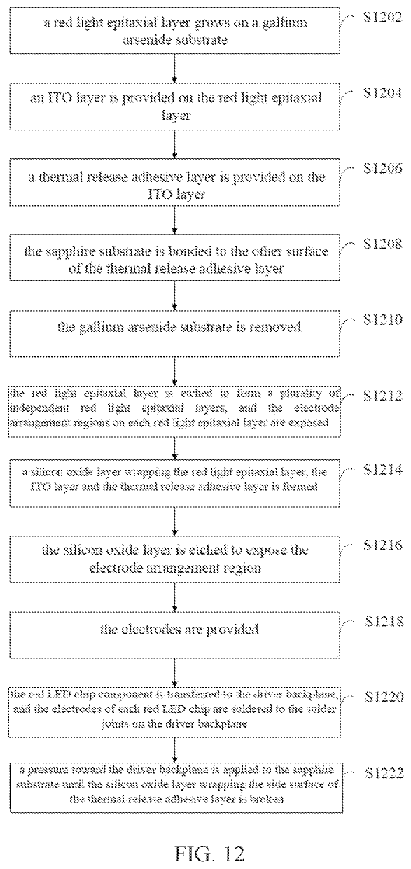

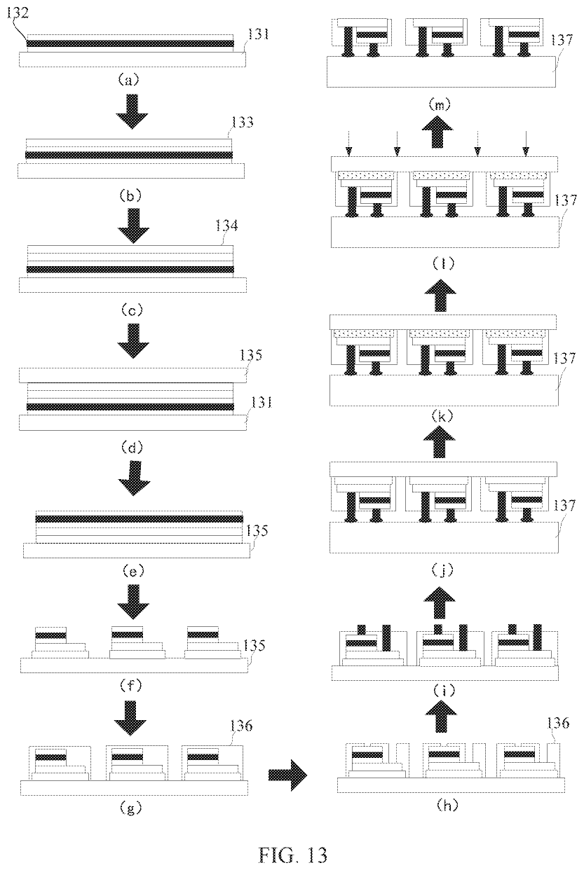

In consideration of the manufacturing process of the display panel which includes the manufacturing process of the red LED chip component, in this embodiment the manufacturing process of the display panel is described as an example, referring to the flow chart shown in FIG. 12 and a schematic diagram of a state change in each manufacture procedure of a process of manufacturing a display panel shown in FIG. 13.

S1202: a red light epitaxial layer grows on a gallium arsenide substrate.

In this embodiment, the gallium arsenide substrate 131 serves as the growth substrate of the red LED chip.

When the red light epitaxial layer 132 grows, the first semiconductor layer, the active layer and the second semiconductor layer grows in sequence, referring to FIG. 13(a).

S1204: an ITO layer is provided on the red light epitaxial layer.

As shown in FIG. 13(b), after the growth of the red light epitaxial layer 132 is completed, an ITO layer 133 can be provided on the red light epitaxial layer 132. It should be understood that the ITO layer 133 serves as a current spreading layer in this embodiment, but in other examples of the embodiment, the current spreading layer may also be implemented in other manners.

S1206: a thermal release adhesive layer is provided on the ITO layer.

In this embodiment, the thermal release adhesive layer 134 is first bonded to the ITO layer 133, as shown in FIG. 13(c). however, in other examples of the embodiment, the thermal release adhesive layer 134 can also be bonded to the sapphire substrate 135.

S1208: the sapphire substrate is bonded to the other surface of the thermal release adhesive layer.

One surface of the thermal release adhesive layer 134 is bonded to the ITO layer 133, and the other surface can be configured to adhere to the sapphire substrate 135, referring to FIG. 13(d). It can be understood that in addition to the sapphire substrate, the insulating substrate can also be other types of substrates.

S1210: the gallium arsenide substrate is removed.

After the ITO layer 133 and the sapphire substrate 135 are bonded through the thermal release adhesive layer, as long as the gallium arsenide substrate 131 is peeled off, the transfer of the red light epitaxial layer 132 from the growth substrate to the sapphire substrate 135 is completed. In some examples of the embodiment, the gallium arsenide substrate 131 may be removed by wet etching, referring to FIG. 13(e).

S1212: the red light epitaxial layer is etched to form a plurality of independent red light epitaxial layers, and the electrode arrangement regions on each red light epitaxial layer are exposed.

After the red light epitaxial layer 132 is transferred to the sapphire substrate 135, the red light epitaxial layer 132 can be etched. In this embodiment, the etching of the red light epitaxial layer 132 needs to achieve two purposes: on one hand, the large-area red light epitaxial layer originally growing on the growth substrate is made into a plurality of independent small-area red light epitaxial layers; on the other hand, the electrode arrangement region of each small-area red light epitaxial layer is exposed, as shown in FIG. 13(f).

It should be understood that after the red light epitaxial layer 132 is transferred to the sapphire substrate 135, the first semiconductor layer in the red light epitaxial layer 132 is at the topmost layer, and the ITO layer 133 is at the bottommost layer. Therefore, the electrode arrangement region of the first electrode is originally exposed, while the electrode arrangement region of the second electrode is hidden under the first semiconductor layer, the active layer, and the second semiconductor layer. Accordingly, before the electrodes are arranged, the first semiconductor layer, the active layer and the second semiconductor layer in the electrode arrangement region of the second electrode need to be etched, so that the ITO layer 133 is exposed to form the electrode arrangement region of the second electrode.

S1214: a silicon oxide layer wrapping the red light epitaxial layer, the ITO layer and the thermal release adhesive layer is formed.

In this embodiment, after the electrode arrangement region of the red light epitaxial layer is exposed, the silicon oxide layer 136 of the red light epitaxial layer 132, the ITO layer 133 and the thermal release adhesive layer 134 can be formed. Referring to FIG. 13(g), the silicon oxide layer 136 together with the sapphire substrate 135 completely wraps the red light epitaxial layer 132, the ITO layer 133 and the thermal release adhesive layer 134.

S1216: the silicon oxide layer is etched to expose the electrode arrangement region.

Since the wrapping of the silicon oxide layer 136 shields the electrode arrangement region, it is also necessary to etch away a region on the silicon oxide layer 136 corresponding to the electrode arrangement region, as shown in FIG. 13(h).

S1218: the electrodes are provided.

After the electrode arrangement regions are exposed, electrodes can be provided in the electrode arrangement regions of two electrodes. For example, in some examples of the embodiment, an electrode metal layer can be formed on the electrode arrangement region by using a PVD process, and then the electrode metal layer is patterned to form the first electrode and the second electrode. The first electrode is arranged on the first semiconductor layer, and the second electrode is arranged on the ITO layer 133, as shown in FIG. 13(i).

So far, the red LED chip component is completed. In the subsequent process, as long as the thermal release adhesive layer 134 fails and the sapphire substrate 135 is peeled off, the red LED chip which is manufactured and separated from the sapphire substrate 135 can be obtained.

S1220: the red LED chip component is transferred to the driver backplane, and the electrodes of each red LED chip are soldered to the solder joints on the driver backplane.

Through the sapphire substrate 135, each of the red LED chips in the red LED chip component can be uniformly transferred to the driver backplane 137, as shown in FIG. 13(j). The solder used in the soldering of the electrodes and the corresponding solder joints can be metals such as indium or bismuth, etc., which can make the thermal release adhesive layer fail during the soldering process, as shown in FIG. 13(k).

In some examples of the embodiment, a driver circuit in the driver backplane 137 can be a Thin Film Transistor (TFT) driver circuit, so that individual driving control of each red LED chip can be implemented.

S1222: a pressure toward the driver backplane is applied to the sapphire substrate until the silicon oxide layer wrapping the side surface of the thermal release adhesive layer is broken.

In this embodiment, since the silicon oxide layer 136 wraps the side surface of the thermal release adhesive layer 134 and is in contact with the sapphire substrate 135, the silicon oxide layer 136 is also bonded to the sapphire substrate 135. Accordingly, the thermal release adhesive layer 134 fails, which cannot make the sapphire substrate 135 separated from the red LED chip. In this embodiment, after the thermal release adhesive layer 134 fails, it is necessary to press the sapphire substrate 135 toward the driver backplane 137 side until the “weakened structure” formed by the silicon oxide layer 136 on the side surface of the thermal release adhesive layer is broken, as shown in FIGS. 13(l) and 13(m).

The red LED chip in this embodiment may include, but is not limited to, a mini-LED, a Micro-LED, or an Organic Light-Emitting Diode (OLED), and the like. The Micro-LED is a new generation of display technology, which has a higher photoelectric efficiency, a higher brightness, a higher contrast, and a lower power consumption than the existing liquid crystal display, and can also be combined with a flexible panel to achieve flexible display. The Micro-LED has the same light-emitting principle as the conventional LED, both are based on the LED chips of the colors RGB to emit light to form three primary colors, thereby realizing the color images.

In this embodiment, the thermal release adhesive layer is used instead of the BCB adhesive layer, the effect of separating the sapphire substrate from the red LED chip based on the thermal effect is implemented, thereby improving the reliability of the red LED chip and enhancing the quality of the red LED chip. Moreover, the direct bonding of the red LED chip and the driver backplane can be implemented, and there is no need to use a temporary substrate to transfer the red LED chip, which simplifies the manufacturing process of the display panel.

It should be understood that the present disclosure is not limited to the above examples. Those of ordinary skill in the art can make improvements or transformations according to the above descriptions, and all these improvements and transformations should fall in the protection scope of the appended claims of the present disclosure.

1. A red LED chip component, comprising:
an insulating substrate;
a plurality of red LED chips arranged on the insulating substrate; and
a thermal release adhesive layer configured to bond the insulating substrate and the red LED chip;
wherein the red LED chip comprises a current spreading layer in contact with the thermal release adhesive layer, a red light epitaxial layer on the current spreading layer, and electrodes respectively electrically connected to two semiconductor layers in the red light epitaxial layer; and
the thermal release adhesive layer is configured to bond the current spreading layer and the insulating substrate in a process of transferring the red light epitaxial layer from a growth substrate to the insulating substrate.

2. The red LED chip component according to claim 1, wherein the red LED chip component further comprises an insulating protection layer wrapping the red LED chip, and a partial region of the electrodes of the red LED chip is exposed out of the insulating protective layer.

3. The red LED chip component according to claim 2, wherein the insulating protection layer wraps a side surface of the thermal release adhesive layer and is in contact with the insulating substrate.

4. The red LED chip component according to claim 2, wherein any two points on a surface of the insulating protection layer away from the insulating substrate are on the same horizontal plane.

5. The red LED chip component according to claim 2, wherein the insulating protection layer is transparent.

6. The red LED chip component according to claim 5, wherein a material of the insulating protection layer is silicon oxide.

7. A method for manufacturing a red LED chip component, comprising:
providing a growth substrate and a red light epitaxial layer formed on a surface of the growth substrate;
providing a current spreading layer on the red light epitaxial layer;
bonding the current spreading layer and an insulating substrate through a thermal release adhesive layer;
removing the growth substrate to transfer the red light epitaxial layer from the growth substrate to the insulating substrate; and
providing electrodes on the red light epitaxial layer to form the red LED chip component comprising a red LED chip.

8. The method for manufacturing the red LED chip component according to claim 7, further comprising,
before providing the electrodes on the red light epitaxial layer,
providing an insulating protection layer wrapping the red light epitaxial layer on the red light epitaxial layer, wherein the insulating protection layer together with the thermal release adhesive layer wraps the red light epitaxial layer and the current spreading layer;
patterning the insulating protection layer to expose an electrode arrangement region.

9. The method for manufacturing the red LED chip component according to claim 7, further comprising:
after providing the electrodes on the red light epitaxial layer,
forming an insulating protection layer wrapping the red LED chip, and a partial region of the electrodes of the red LED chip is exposed out of the insulating protection layer.

10. The method for manufacturing the red LED chip component according to claim 7, wherein the bonding the current spreading layer and the insulating substrate through the thermal release adhesive layer comprises:
providing the thermal release adhesive layer on the current spreading layer;
bonding the insulating substrate to the current spreading layer through the thermal release adhesive layer.

11. The method for manufacturing the red LED chip component according claim 7, wherein the bonding the current spreading layer and the insulating substrate through the thermal release adhesive layer comprises:
providing the thermal release adhesive layer on the insulating substrate;
bonding the current spreading layer to a surface of the thermal release adhesive layer away from the insulating substrate.

12. The method for manufacturing the red LED chip component according claim 7, wherein the bonding the current spreading layer and the insulating substrate through the thermal release adhesive layer comprises:
providing a first thermal release adhesive layer on the current spreading layer, and providing a second thermal release adhesive layer on the insulating substrate;
bonding the first thermal release adhesive layer and the second thermal release adhesive layer.

13. A method for manufacturing a red LED chip, comprising:
manufacturing a red LED chip component according to the method for manufacturing the red LED chip component of claim 7; and
heating up to make the thermal release adhesive layer fail and separate the insulating substrate from the red LED chip.

14. A method for manufacturing a display panel, comprising:
manufacturing a red LED chip component according to the method for manufacturing the red LED chip component of claim 7; wherein an arrangement of each red LED chip in the red LED chip component satisfies a deployment requirement of the red LED chip on a driver backplane;
soldering an electrode of each red LED chip in the red LED chip component to a solder joint on the driver backplane;
after the thermal release adhesive layer fails due to heating, removing the insulating substrate and the failed thermal release adhesive layer.

15. The method for manufacturing the display panel according to claim 14, wherein the soldering the electrode of each red LED chip in the red LED chip component to the solder joint on the driver backplane comprises:
soldering the electrode to the solder joint at a soldering temperature higher than a temperature at which the thermal release adhesive layer fails.

16. The method for manufacturing the display panel according to claim 15, wherein the soldering the electrode to the solder joint at the soldering temperature higher than the temperature at which the thermal release adhesive layer fails comprises:
soldering the electrode to the solder joint with indium or bismuth as a solder.

17. The method for manufacturing the display panel according to claim 14, wherein in response to that the red LED chip comprises the insulating protective layer, and the insulating protection layer wraps a side surface of the thermal release adhesive layer and is in contact with the insulating substrate, the removing the insulating substrate and the failed thermal release adhesive layer after the thermal release adhesive layer fails due to the heating comprises:
applying a pressure to the insulating substrate toward the driver backplane until the insulating protection layer wrapping the side surface of the thermal release adhesive layer is broken.

18. A display panel, wherein the display panel is manufactured according to the method for manufacturing the display panel of claim 14.
